(19) United States
(12) Patent Application Publication
(10) Pub. No.: US 2017/0194329 A1
(43) Pub. Date: Jul. 6, 2017

(54) SEMICONDUCTOR DEVICE

(71) Applicant: SOCIONEXT INC., Yokohama-shi (JP)

(72) Inventor: Junji IWAHORI, Akisima (JP)

(21) Appl. No.: 15/205,421

(22) Filed: Jul. 8, 2016

(30) Foreign Application Priority Data
Jan. 4, 2016 (JP) 2016-000020

(51) Int. Cl. H01L 27/11; H01L 27/088; H01L 23/528

(52) U.S. Cl. CPC H01L 27/1104; H01L 23/5286; H01L 27/0886

(57) ABSTRACT

A cell includes a plurality of fin transistors formed in a semiconductor substrate. In the cell, a fin serving as a source and drain of each of the plurality of fin transistors is arranged in plurality at a first pitch in a first direction. Moreover, the cell height that is the length in the first direction of the cell is an n multiple (n is an integer) of half the length of the first pitch. Wires are connected to the cell, and are arranged at a second pitch, which is a 1/m multiple (m is an integer) of the cell height in the first direction.

### CROSS-REFERENCE TO RELATED APPLICATION

This application is based upon and claims the benefit of priority of the prior Japanese Patent Application No. 2016-000020, filed on Jan. 4, 2016, the entire contents of which are incorporated herein by reference.

### FIELD

Embodiments discussed herein relate to semiconductor devices.

### BACKGROUND

There is known a fin transistor having a structure different from that of a planar transistor. The fin transistor includes a source and drain called a fin that protrudes on a semiconductor substrate, and a gate that is arranged perpendicular to the fin so as to wrap the fin.

Because fin transistors are simultaneously formed across a wafer, the fins have a common pitch across the wafer and across a chip. Conventionally, in a cell including fin transistors, the length of the cell (hereinafter, referred to as a cell height) in a direction in which the fins are arranged is sometimes set to an integral multiple of the pitch of the fins. The cell height is also defined by the minimum wiring pitch (in a metal layer) that is based on a design standard.

U.S. Patent Application Publication No. 2014/0346662

U.S. Patent Application Publication No. 2014/0181774

U.S. Patent Application Publication No. 2014/0097493

U.S. Patent Application Publication No. 2012/0280331

However, due to a difference between the pitch of the fins and the minimum wiring pitch, there is a problem that it is unable to finely determine the size of a cell in determining the cell height based on the both pitches.

### SUMMARY

According to one aspect, there is provided a semiconductor device including: a semiconductor substrate; a cell including a plurality of fin transistors formed in the semiconductor substrate, wherein a fin serving as a source and drain of each of the plurality of fin transistors is arranged in plurality at a first pitch in a first direction and a cell height of the cell that is a length in the first direction is an n multiple (n is an integer) of half a length of the first pitch; and a plurality of wires connected to the cell and arranged at a second pitch that is a 1/m multiple (m is an integer) of the cell height in the first direction.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a plan view illustrating an example of a semiconductor device of a first embodiment;

FIG. 2 is a table indicating an exemplary relationship among an integer n, a cell height Hsel, a pitch Pm, and a coefficient k;

FIG. 3 illustrates an example of a semiconductor device of a comparative example;

FIG. 4 is a table indicating an exemplary relationship between an integer na and a cell height Hsela in the semiconductor device of the comparative example;

FIG. 5 is a perspective view illustrating an example of a fin transistor;

FIG. 6 illustrates an exemplary arrangement of a cell;

FIG. 7 is an exemplary cross sectional view of the semiconductor device;

FIG. 8 illustrates an exemplary chip image of the semiconductor device; and

FIG. 9 illustrates a variation of the semiconductor device.

### DESCRIPTION OF EMBODIMENTS

Several embodiments will be described below with reference to the accompanying drawings, wherein like reference numerals refer to like elements throughout.

### First Embodiment

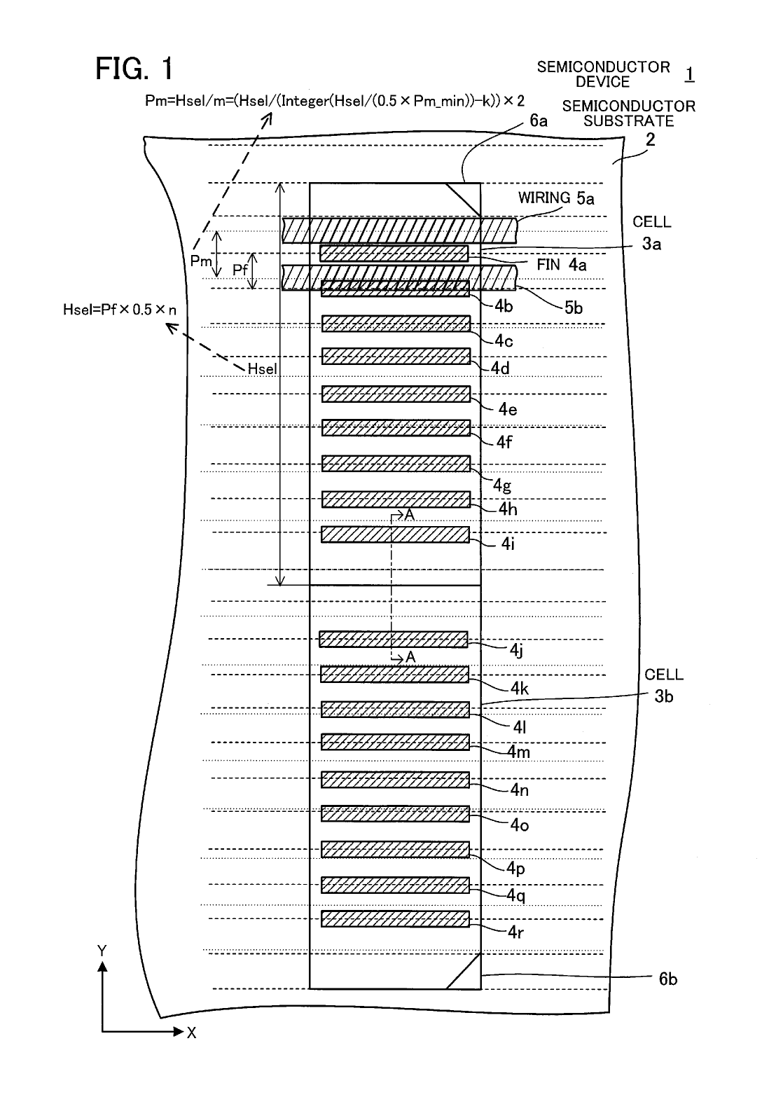

FIG. 1 is a plan view illustrating an example of a semiconductor device of a first embodiment.

A semiconductor device 1 includes a semiconductor substrate 2 and a plurality of cells 3a and 3b formed in the semiconductor substrate 2. Although in the example of FIG. 1, for simplicity of illustration, two cells 3a and 3b are illustrated, three or more cells may be formed in the semiconductor substrate 2.

The cells 3a and 3b are standard cells, for example. Note that, the standard cell is a circuit serving as a basic unit that performs a specified logic function, for example such as an inverter or a flip-flop. The cell height and horizontal width of a standard cell are standardized.

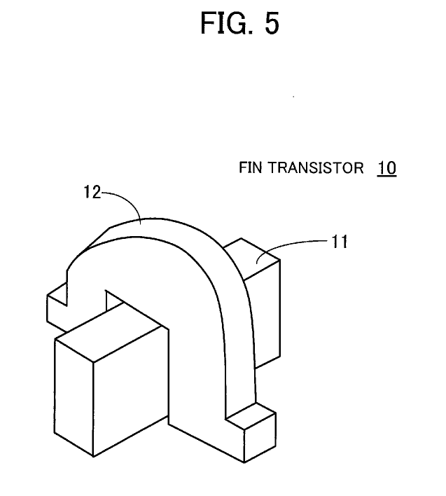

The cells 3a and 3b each include a plurality of fin transistors (see FIG. 5). In FIG. 1, there are illustrated fins 4a, 4b, 4c, 4d, 4e, 4f, 4g, 4h, and 4i serving as a source and drain of each of the plurality of fin transistors included in the cell 3a. Moreover, there are illustrated fins 4j, 4k, 4l, 4m, 4n, 4o, 4p, 4q, and 4r serving as a source and drain of each of the plurality of fin transistors included in the cell 3b. The illustration of the gate of the fin transistor is omitted. The fins 4a to 4r each extending in the X direction are arranged at a common pitch Pf in the Y direction in the semiconductor device 1.

In the semiconductor device 1 of the embodiment, the cell height Hsel of the cell 3a is set to an n multiple (n is an integer) of half the length of the pitch Pf. That is, Hsel=Pf×0.5×n.

In the example of FIG. 1, Hsel=Pf×0.5×23 because n is an odd number 23. Moreover, in the example of

FIG. 1, the cell 3b has the same cell height as the cell 3a.

Note that, the lower limit of n is determined, for example, based on the minimum number of fins needed in order to function as a standard cell and/or on the design standards (e.g., a design standard such as “a fin is unable to be arranged because a space is needed in order to separate the gates of the cells 3a and 3b from each other”).

The horizontal width (the length in the X direction) of each of the cells 3a and 3b is set to, for example, an integral multiple of the length of a pitch at which a gate, not illustrated, is arranged.

Moreover, the semiconductor device 1 includes wires 5a and 5b whose principal axes are the X direction in a P&R (Place and Route) process. The wires 5a and 5b are connected to the cell 3a. The wires 5a and 5b are, for example, formed in a second metal layer that is used for transmission and reception of a signal between the cells in the X direction, and are electrically connected to a first metal layer (e.g., used for the local wiring inside the cell 3a), not illustrated. Note that, although in FIG. 1, for simplicity of illustration, the number of wires connected to the cell 3a and extending in the X direction is set to two, the number of wires is not limited to two but three or more wires may be arranged at a pitch Pm in the Y direction. Here, needless to say that a wire extending in the Y direction may be connected to the cell 3a. Although illustration is omitted, wires are similarly connected also to the cell 3b.

In the semiconductor device 1 of the embodiment, the pitch Pm of wires in the Y direction is set to a 1/m multiple (m is an integer) of the cell height Hsel. Moreover, the pitch Pm may be expressed as Formula (1) below using a minimum wiring pitch Pm_min based on the design standard.

Pm=(Hsel/(Integer(Hsel/(0.5×Pm_min))−k))×2 (1)

In Formula (1), Integer(Hsel/(0.5×Pm_min)) indicates an integral part of Hsel/(0.5×Pm_min). k is a coefficient for making the cell height Hsel dividable by Integer (Hsel/(0.5×Pm_min)).

Note that a power supply line or ground line (not illustrated) is provided in the upper and lower ends of each of the cells 3a and 3b. In the cells 3a and 3b, portions with triangular marks 6a and 6b indicate the lower end, while portions without the marks 6a and 6b indicate the upper end. The cell 3a is flipped upside down with respect to the cell 3b, which is adjacent to the cell 3a in the Y direction, in order to share the power supply line or ground line with the cell 3b. That is, the cell 3a is arranged so that the lower end thereof (the side with the mark 6a) is located on the upper side of the paper space.

The cells 3a and 3b are arranged in this manner, so that even when n of Hsel=Pf×0.5×n is an odd number as illustrated in FIG. 1, the positional relationship of the fins 4a to 4i of the cell 3a and the positional relationship of the fins 4j to 4r of the cell 3b may be made the same.

For example, the fin 4i of the cell 3a is arranged at a location that is 1.5×Pf away from the upper end (the end on the lower side of the paper space because it is flipped) of the cell 3a. On the other hand, also in the cell 3b, the fin 4j is arranged at a location that is 1.5×Pf away from the upper end of the cell 3b. Similarly, the fin 4h of the cell 3a is arranged at a location corresponding to the location of the fin 4k of the cell 3b, and the fin 4g of the cell 3a is arranged at a location corresponding to the location of the fin 4l of the cell 3b. Because the positional relationship of the fins 4a to 4i of the cell 3a and the positional relationship of the fins 4j to 4r of the cell 3b may be made the same in this manner, the cells 3a and 3b may have the same structure.

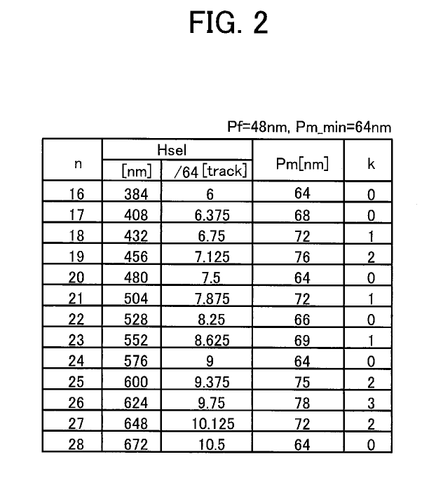

FIG. 2 is a table indicating an exemplary relationship among the integer n, the cell height Hsel, the pitch Pm, and the coefficient k. Note that, in the example of FIG. 2, assume that the pitch Pf is 48 nm and the minimum wiring pitch Pm_min based on a design standard is 64 nm.

For example, when n=23 as in the case of the semiconductor device 1 illustrated in FIG. 1, the cell height Hsel is 552 nm (8.625 tracks when the wiring pitch Pm_min=64 nm is defined as one track).

At this time, the pitch Pm is 69 nm when k=1 in Formula (1). That is, the pitch Pm is 1/8 times the cell height Hsel.

As described above, in the semiconductor device 1 of the embodiment, the cell height Hsel is determined independently from the pitch Pm. Moreover, the cell height

Hsel is determined by the relationship Hsel=Pf×0.5×n and thus may be finely selected. In the example of FIG. 2, the cell height Hsel is selectable in the unit of 24 nm. Therefore, the options of cell size may be increased.

### COMPARATIVE EXAMPLE

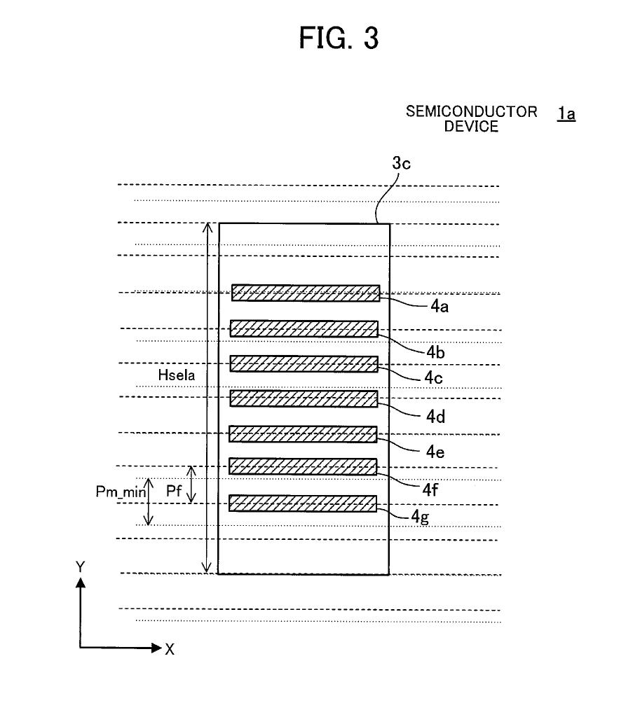

FIG. 3 illustrates an example of a semiconductor device of a comparative example. The same reference sign is given to the same element as in the semiconductor device 1 of FIG. 1.

In a semiconductor device la illustrated in FIG. 3, a cell height Hsela of a cell 3c is an na multiple (na is an integer) of the least common multiple of the length of half the minimum wiring pitch Pm_min in the Y direction based on a design standard and the pitch Pf.

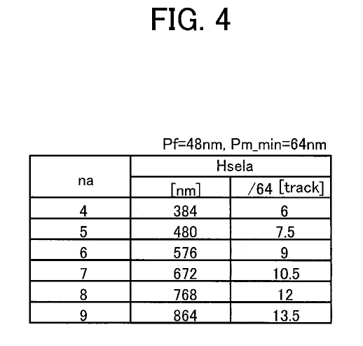

FIG. 4 is a table indicating an exemplary relationship between the integer na and the cell height Hsela in the semiconductor device of the comparative example. Note that, in the example of FIG. 4, assume that the pitch Pf is 48 nm and the minimum wiring pitch Pm_min based on a design standard is 64 nm.

For example, in the case of na=6, the cell height Hsela is 576 nm (corresponding to 9 tracks when the wiring pitch Pm_min=64 nm is defined as one track).

As illustrated in FIG. 4, in the semiconductor device la of the comparative example, the cell height Hsela is selectable only in the unit of 96 nm. In contrast, in the semiconductor device 1, as illustrated in FIG. 2, the cell height Hsel is selectable with ¼ the fineness of the semiconductor device la of the comparative example.

Moreover, because the pitch Pm is determined based on the cell height Hsel, the mismatch with the pitch Pf will not reduce the range of the option of the cell height Hsel.

(An Example of the Fin Transistor)

FIG. 5 is a perspective view illustrating an example of the fin transistor.

A fin transistor 10 is an FET (Field Effect Transistor), and includes a fin 11 serving as the source and drain and a gate 12 that is arranged perpendicular to the fin 11 so as to wrap the fin 11, as illustrated in FIG. 5.

The cells 3a and 3b illustrated in FIG. 1 include a plurality of fin transistors 10 as described above.

(Exemplary Arrangement of a Cell)

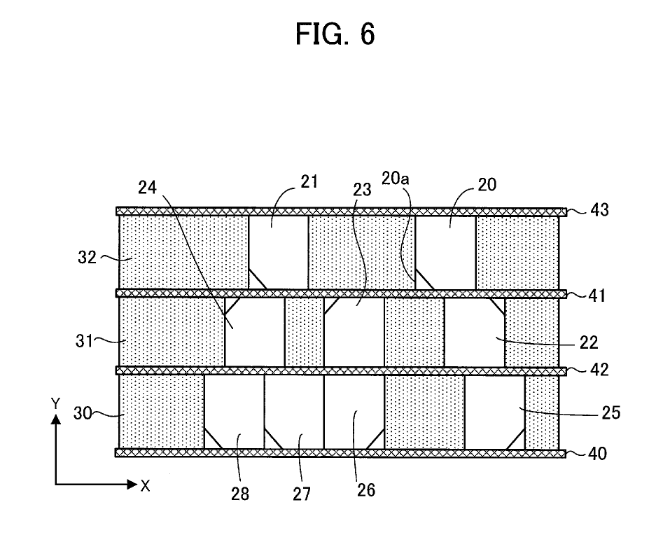

FIG. 6 illustrates an exemplary arrangement of the cell.

Each of cells 20 to 28 has, for example, a structure similar to that of each of the cells 3a and 3b and is arranged in areas 30, 31 and 32 that are partitions of the cell height Hsel (Hsel=Pf×0.5×n) in the Y direction. Note that, in the upper and lower ends of the cells 20 to 28 there are provided ground lines 40 and 41 or power supply lines 42 and 43. In the cells 20 to 28, a portion with a triangular mark (e.g., mark 20a) is the lower end while a portion without the triangular mark is the upper end.

In the example of FIG. 6, the ground lines 40 and 41 are provided in the lower end of the cells 20 to 28 while the power supply lines 42 and 43 are provided in the upper end. The ground lines 40 and 41 and power supply lines 42 and 43 are connected to fin transistors, not illustrated, inside the cells 20 to 28.

As illustrated in FIG. 6, the cells arranged in the area adjacent in the Y direction are reversed (flipped upside down) in the Y direction so as to share the power supply line or ground line. For example, the cells 22, 23 and 24 arranged in the area 31 are reversed and arranged with respect to the cells 20 and 21 in the Y direction so as to share the ground line 41 with the cells 20 and 21 arranged in the area 32. That is, the cells 22 to 24 are flipped upside down so that the lower end thereof is located on the upper side of the paper space.

By arranging in this manner, even if n of Hsel=Pf×0.5×n is an odd number, the positional relationship of the fins in the cells 20 to 28 may be made the same as the positional relationship of the fins 4a to 4r in the above-described cells 3a and 3b.

(Example of Cross Sectional Structure)

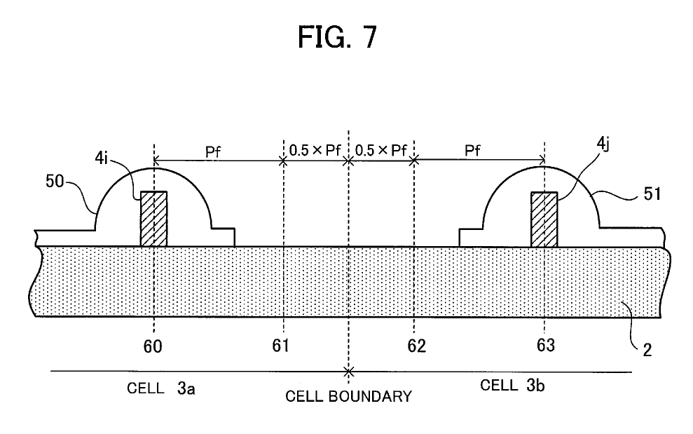

FIG. 7 is an exemplary cross sectional view of the semiconductor device.

In FIG. 7, there is illustrated the cross section of the semiconductor device 1 along an A-A line of FIG. 1. In FIG. 7, the same element as the element illustrated in FIG. 1 is given the same reference sign.

In FIG. 7, there are illustrated gates 50 and 51 whose illustrations are omitted in FIG. 1.

Grids 60, 61, 62 and 63 are set at each pitch Pf, but in order to separate the gates 50 and 51 from each other at a cell boundary, the arrangement of a fin is prohibited within one grid from the cell boundary, for example. This is for example because if there is a fin in the grids 61 and 62, it is difficult to cut the gates 50 and 51, which are formed so as to wrap the fins 4i and 4j, between the cells 3a and 3b.

When the cell height Hsela is set to Hsela=Pf×n as in the semiconductor device la of the comparative example as illustrated in FIG. 3, a fin closest to the cell boundary is arranged in a grid that is Pf×2 away from the cell boundary. In contrast, in the semiconductor device 1 of the embodiment, the cell height Hsel is set to Hsel=Pf×0.5×n, so that as illustrated in FIG. 7, the fins 4i and 4j may be arranged in the grids 60 and 63 that are Pf×1.5 away from the cell boundary. Therefore, the wasteful area near the cell boundary may be reduced. Thus, the number of fins in one cell may be increased.

(Exemplary Chip Image)

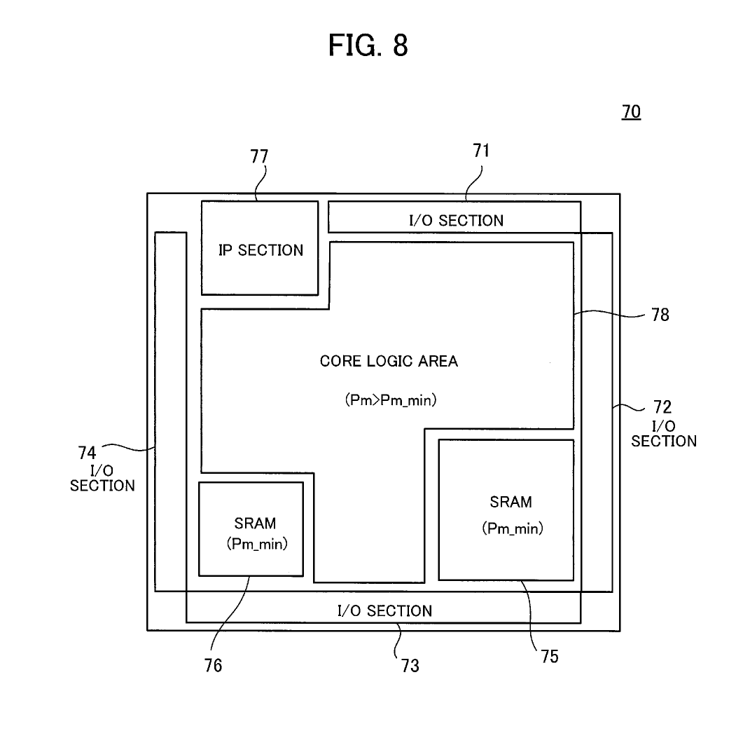

FIG. 8 illustrates an exemplary chip image of the semiconductor device.

A semiconductor device 70 includes: I/O (Input/Output) sections 71, 72, 73 and 74; SRAMs (Static Random Access Memory) 75 and 76; an IP (Intellectual Property) section 77; and a core logic area 78.

The cells 3a and 3b as illustrated in FIG. 1 are arranged as a standard cell in the core logic area 78 as illustrated in FIG. 8.

In the semiconductor device 70 of the embodiment, the pitch of wires in the arrangement direction of the fin of the core logic area 78 may be a value larger than the pitch of wires of a cell (macro cell) included in macros, such as the I/O sections 71 to 74, the SRAMs 75 and 76, and the IP section 77.

For example, in the macro cell of the SRAMs 75 and 76, wires (except the word line and column selection line) are formed at the minimum wiring pitch Pm_min that is based on a design standard, in order to reduce the size of each of the SRAMs 75 and 76. In contrast, in the core logic area 78, wires are formed at the above-described pitch Pm (>Pm_min).

(Variation of the Semiconductor Device)

Although in the semiconductor device 1 illustrated in FIG. 1, the cell height Hsel of each of the cells 3a and 3b is an odd number multiple of the pitch Pf×0.5, it may be set to an even number multiple of the pitch Pf×0.5.

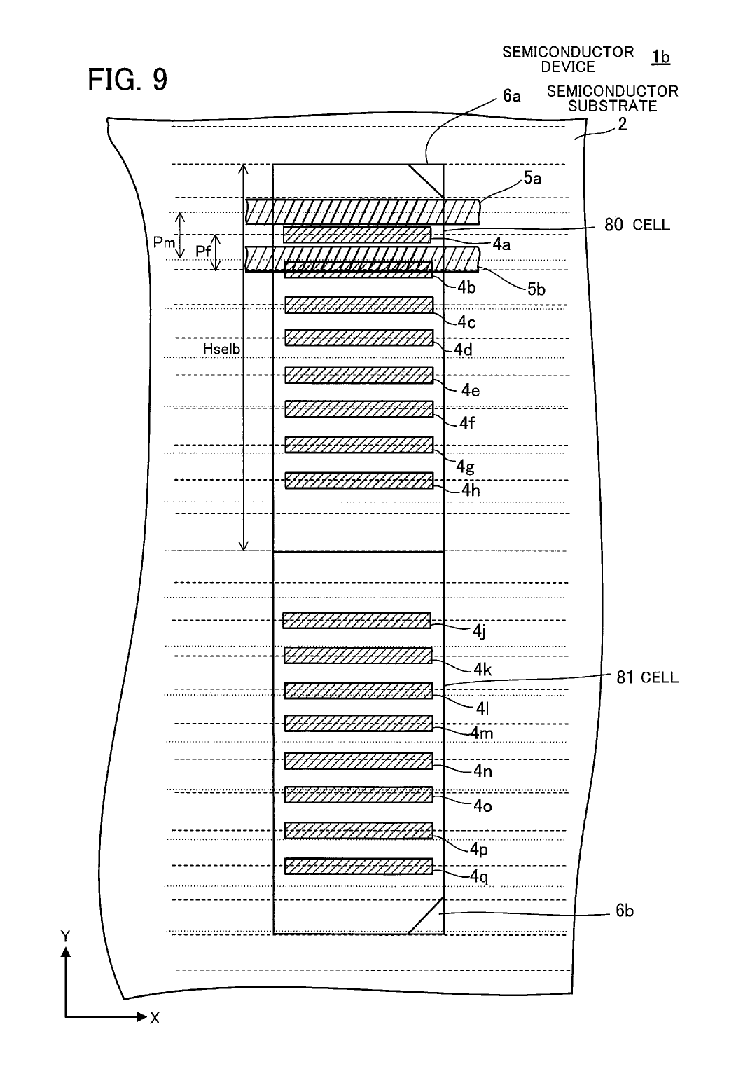

FIG. 9 illustrates a variation of the semiconductor device. In FIG. 9, the same element as the element illustrated in FIG. 1 is given the same reference sign.

In a cell 80 of a semiconductor device 1b illustrated in FIG. 9, a cell height Hselb is Hselb=Pf×0.5×22.

In the foregoing, one aspect of the semiconductor device of this invention has been described based on the embodiments, but this is just one example and is therefore not limited to the above-described description.

According to the semiconductor device of the disclosure, the options of the size of a cell may be increased.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

1. A semiconductor device comprising:
a semiconductor substrate;
a cell including a plurality of fin transistors formed in the semiconductor substrate, wherein a fin serving as a source and drain of each of the plurality of fin transistors is arranged in plurality at a first pitch in a first direction and a cell height of the cell that is a length in the first direction is an odd number multiple of half a length of the first pitch; and
a plurality of wires connected to the cell and arranged at a second pitch that is a 1/m multiple (m is an integer) of the cell height in the first direction.

2. The semiconductor device according to claim 1, wherein the cell is a standard cell,
wherein the standard cell is arranged in plurality in a plurality of areas provided by partitioning the 20 semiconductor substrate, the plurality of areas having the cell height in the first direction, and
wherein a first standard cell arranged in a first area among the plurality of areas is reversely arranged in the first direction with respect to a second standard cell, which is arranged in a second area adjacent to the first area, so as to share one of a power supply line and a ground line with the second standard cell.

3.-9. (canceled)

10. A semiconductor device comprising:
a semiconductor substrate; and
a cell including a plurality of fin transistors formed in the semiconductor substrate, wherein a fin serving as a source and drain of each of the plurality of fin transistors is arranged in plurality at a first pitch in a first direction and a cell height of the cell that is a length in the first direction is an odd number multiple of half a length of the first pitch.
